(19) United States
(12) Patent Application Publication
(10) Pub. No.: US 2024/0389437 A1
(43) Pub. Date: Nov. 21, 2024

(54) DISPLAY DEVICE AND METHOD OF FABRICATING THE SAME

(71) Applicant: Samsung Display Co., LTD., Yongin-si (KR)

(72) Inventors: Tae Oh KIM, Yongin-si (KR); Yong Hoon KWON, Yongin-si (KR); Byung Hoon KIM, Yongin-si (KR); Jeong Jin PARK, Yongin-si (KR); Sang Chul BYUN, Yongin-si (KR)

(73) Assignee: Samsung Display Co., LTD., Yongin-si (KR)

(21) Appl. No.: 18/600,771

(22) Filed: Mar. 11, 2024

(30) Foreign Application Priority Data
May 15, 2023 (KR) 10-2023-0062547

(51) Int. Cl. H10K 59/80; H10K 59/12; H10K 59/127; H10K 59/38

(52) U.S. Cl. CPC H10K 59/879; H10K 59/1201; H10K 59/127; H10K 59/38; H10K 59/873

(57) ABSTRACT

A display device includes a first substrate, an organic light-emitting-element layer disposed on the first substrate, an encapsulation layer disposed on the organic light-emitting-element layer, and a lens array layer disposed on the encapsulation layer. The lens array layer includes a lens layer including multiple lenses, and a second substrate disposed (e.g., directly disposed) on the lenses. The second substrate includes multiple concave depressions corresponding to shapes of the lenses.

### CROSS-REFERENCE TO RELATED APPLICATION(S)

This application claims priority to and the benefit of Korean Patent Application No. 10-2023-0062547 filed on May 15, 2023 in the Korean Intellectual Property Office, the entire contents of which are incorporated herein by reference.

### BACKGROUND

### 1. Technical Field

Various embodiments of the disclosure relate to a display device and a method of fabricating the display device.

### 2. Description of the Related Art

Micro-lenses may be used to increase the resolution of respective pixels included in a display device.

However, recently, with the miniaturization of optical components and advancements in application technologies, in lieu of earlier geometric optic-based lenses, application devices incorporating micro-sized lens arrays have been applied to display devices related to augmented reality/virtual reality (AR/VR).

### SUMMARY

Embodiments of the disclosure reduce the size of each pixel in a display device and thus reduce the width of each pixel and the thickness of the display device.

Embodiments of the disclosure facilitate a process of fabricating the display device by eliminating the step of forming an adhesive layer for attaching a micro-lens to a substrate, as well as the step of forming a dam structure for forming the adhesive layer.

Embodiments of the disclosure may also be directed to a method of fabricating the display device.

In accordance with an embodiment of the disclosure, a display device may include a first substrate; an organic light-emitting-element layer disposed on the first substrate; an encapsulation layer disposed on the organic light-emitting-element layer; and a lens array layer disposed on the encapsulation layer. The lens array layer may include a lens layer including multiple lenses; and a second substrate disposed (e.g., directly disposed) on the lenses. The second substrate may include multiple concave depressions corresponding to shapes of the lenses.

In accordance with an embodiment of the disclosure, the lenses may include an optically clear material.

In accordance with an embodiment of the disclosure, the lenses may include at least one of an optically clear resin (OCR) and an optically clear adhesive (OCA).

In accordance with an embodiment of the disclosure, the display device may further include a color filter layer disposed between the encapsulation layer and the lens array layer, the color filter layer may include first to third color filters. The lenses may include a first lens disposed on the first color filter, a second lens disposed on the second color filter, and a third lens disposed on the third color filter.

In accordance with an embodiment of the disclosure, the concave depressions may include a first concave depression, a second concave depression, and a third concave depression. The first lens may be disposed in the first concave depression. The second lens may be disposed in the second concave depression. The third lens may be disposed in the third concave depression.

In accordance with an embodiment of the disclosure, the second substrate may include a glass substrate.

In accordance with an embodiment of the disclosure, the first substrate may include first to third sub-pixels. The organic light-emitting-element layer may include a first pixel electrode layer including respective first pixel electrodes of the first to third sub-pixels, the first pixel electrode may be spaced apart from each other; an emission layer disposed on the first pixel electrode layer; and a second pixel electrode disposed on the emission layer.

In accordance with an embodiment of the disclosure, the first pixel electrode of the first sub-pixel may overlap the first color filter. The first pixel electrode of the second sub-pixel may overlap the second color filter. The first pixel electrode of the third sub-pixel may overlap the third color filter.

In accordance with an embodiment of the disclosure, the first substrate may include a silicon substrate.

In accordance with an embodiment of the disclosure, the lenses may have a same shape.

In accordance with an embodiment of the disclosure, a method of fabricating a display device may include providing a pixel having a stack structure, the pixel may include an organic light-emitting-element layer; providing a base substrate; forming a micro-pattern including multiple concave depressions in a base substrate; filling the concave depressions with an optically clear material; and disposing the base substrate over the pixel.

In accordance with an embodiment of the disclosure, the forming of the micro-pattern may include removing portions of the base substrate by irradiating a laser beam onto the base substrate.

In accordance with an embodiment of the disclosure, the laser beam may have a wavelength in a range of approximately 100 nm to approximately 400 nm.

In accordance with an embodiment of the disclosure, the forming of the micro-pattern may further include etching the base substrate using a chemical solution. The laser beam may have a wavelength in a range of approximately 750 nm to approximately 1000 nm.

In accordance with an embodiment of the disclosure, the method may further include forming a color filter layer on the organic light-emitting-element layer. The concave depressions filled with the optically clear material may contact (e.g., directly contact) an upper surface of the color filter layer.

In accordance with an embodiment of the disclosure, in the forming of the micro-pattern, the concave depressions may be spaced apart from each other.

In accordance with an embodiment of the disclosure, the base substrate may include a glass substrate.

In accordance with an embodiment of the disclosure, the optically clear material may include at least one of an optically clear resin (OCR) and an optically clear adhesive (OCA). In accordance with an embodiment of the disclosure, the stack structure may include a first substrate; the organic light-emitting-element layer disposed on the first substrate; an encapsulation layer disposed on the organic light-emitting-element layer; and the color filter layer disposed on the encapsulation layer, the color filter layer may include first to third color filters, the first to third color filters may be spaced apart from each other in a first direction.

In accordance with an embodiment of the disclosure, the concave depressions may include a first concave depression, a second concave depression, and a third concave depression. The first concave depression may overlap the first color filter. The second concave depression may overlap the second color filter. The third concave depression may overlap the third color filter.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device in accordance with embodiments of the disclosure;

FIGS. 2A to 2C are plan views illustrating embodiments of a pixel of FIG. 1;

FIG. 3 is a schematic diagram of an equivalent circuit of a sub-pixel included in the pixel of FIGS. 2A to 2C;

FIG. 4A is a schematic sectional view illustrating an embodiment of a light emitting element of FIG. 3;

FIG. 4B is a schematic sectional view illustrating an embodiment of the light emitting element of FIG. 3;

FIG. 5 is a schematic sectional view illustrating a stack structure of a pixel including the light emitting element of FIG. 3;

FIG. 6 is a schematic sectional view illustrating a comparative example of a pixel included in the display device;

FIG. 7 is a schematic sectional view illustrating an embodiment of a stack structure and a lens array layer of the pixel of FIG. 5;

FIGS. 8A to 8C are schematic diagrams successively illustrating an embodiment of a method of fabricating the lens array layer of FIG. 7;

FIGS. 9A to 9D are schematic diagrams successively illustrating an embodiment of the method of fabricating the lens array layer of FIG. 7;

FIG. 10 is a schematic sectional view illustrating a method of fabricating the display device of FIG. 1; and

FIGS. 11 and 12 illustrate examples of an electronic device including the display device of FIG. 1.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing exemplary features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element or layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments of the disclosure will be described in more detail with reference to the accompanying drawings.

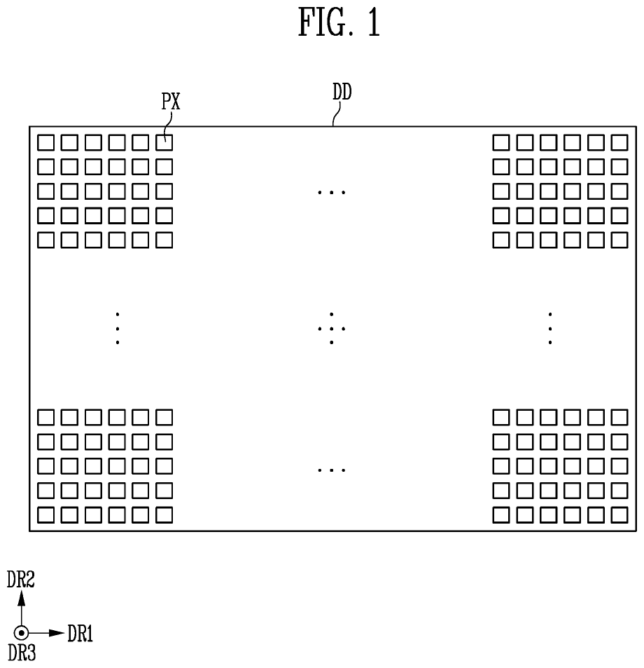

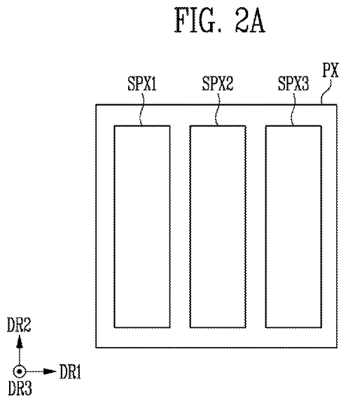

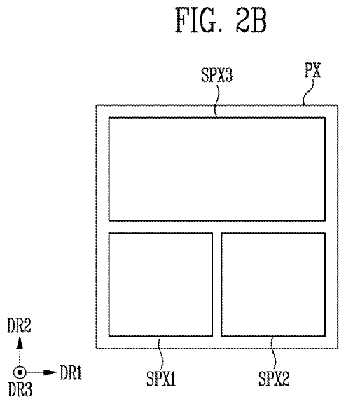

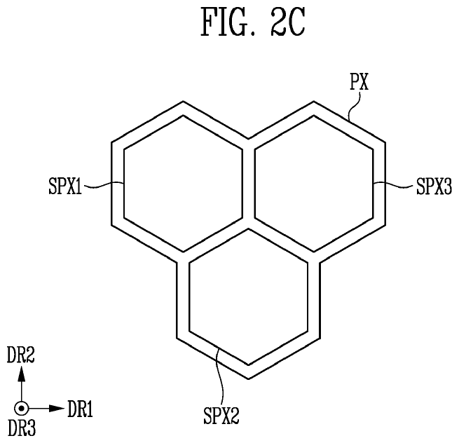

FIG. 1 is a schematic plan view illustrating a display device DD in accordance with embodiments of the disclosure. FIGS. 2A to 2C are plan views illustrating embodiments of a pixel PX of FIG. 1.

Referring to FIG. 1, the display device DD may be a device configured to display a video or a static image, and may be used not only as portable electronic devices such as a mobile phone, a smart phone, a tablet personal computer (a tablet PC), a smart watch, a watch phone, a mobile communication terminal, an electronic notebook, an electronic book, a portable multimedia player (PMP), a navigation device, and an ultra mobile PC (UMPC), but also as display screens of various products such as a television, a notebook, a monitor, an advertisement panel, and an internet of things (IoT) device.

The display device DD may be formed of a rectangular panel having long sides extending in a first direction DR1, and short sides extending a second direction DR2 intersecting the first direction DR1. Corners where the long sides extending in the first direction DR1 and the short sides extending in the second direction DR2 meet may be rounded with a certain curvature or may be formed at a right angle. The plane shape of the display device DD may not be limited to a rectangular shape, and may have other polygonal shapes, a circular shape, or an elliptical shape. The display device DD may be formed to be planar, but it may not be limited thereto. For example, the display device DD may include a curved surface which may be formed on each of left and right side edges thereof and has a constant curvature or a varying curvature. In addition, the display device DD may be formed to be flexible so that the display device DD can be bent, curved, folded, or rolled.

The display device DD may further include pixels PX configured to display an image, scan lines extending in the first direction DR1, and data lines extending in the second direction DR2. The pixels PX may be arranged in the form of a matrix in the first direction DR1 and the second direction DR2.

Referring to FIGS. 1 to 2C, each of the pixels PX may include multiple sub-pixels SPX1, SPX2, and SPX3. Although FIGS. 2A to 2C illustrate that each of the pixels PX includes three sub-pixels SPX1, SPX2, and SPX3 (i.e., a first sub-pixel SPX1, a second sub-pixel SPX2, and a third sub-pixel SPX3) the disclosure may not be limited thereto.

The first sub-pixel SPX1, the second sub-pixel SPX2, and the third sub-pixel SPX3 may be electrically connected to at least one data line among the data lines and at least one scan line among the scan lines.

Referring to FIGS. 2A to 2C, each of the first sub-pixel SPX1, the second sub-pixel SPX2, and the third sub-pixel SPX3 may have a rectangular shape, a square shape, or a rhombus shape, in a plan view. For example, each of the first sub-pixel SPX1, the second sub-pixel SPX2, and the third sub-pixel SPX3 may have a rectangular planar shape having short sides extending in the first direction DR1 and long sides extending in the second direction DR2. Alternatively, in an embodiment, each of the first sub-pixel SPX1, the second sub-pixel SPX2, and the third sub-pixel SPX3 may have a square or rhombus planar shape having sides having the same length in the first direction DR1 and the second direction DR2. The first sub-pixel SPX1, the second sub-pixel SPX2, and the third sub-pixel SPX3 may be arranged in the first direction DR1. In an embodiment, the first to third sub-pixels SPX1 to SPX3 may have the same surface area, but the disclosure may not be limited thereto. For example, the surface area of at least one of the first to third sub-pixels SPX1 to SPX3 may instead differ from that of another one. Alternatively, any two of the surface areas of the first sub-pixel SPX1, the surface area of the second sub-pixel SPX2, and the surface area of the third sub-pixel SPX3 may be substantially the same as each other, and a remaining one may be different from the two. Alternatively, the surface area of the first sub-pixel SPX1, the surface area of the second sub-pixel SPX2, and the surface area of the third sub-pixel SPX3 may be different from each other.

Referring to FIG. 2B, the first sub-pixel SPX1 may be arranged with either the second sub-pixel SPX2 or the third sub-pixel SPX3 in the first direction DR1, and may be arranged with the remaining one in the second direction DR2. Alternatively, the second sub-pixel SPX2 and any one of the first sub-pixel SPX1 and the third sub-pixel SPX3 may be arranged in the first direction DR1, and a remaining one may be arranged in the second direction DR2. In an embodiment, the third sub-pixel SPX3 may be positioned in the second direction DR2 from the first sub-pixel SPX1 and the second sub-pixel SPX2. In an embodiment, the surface areas of the first and second sub-pixels SPX1 and SPX2 may be substantially the same as each other. The surface area of the third sub-pixel SPX3 may differ from the surfaces areas of the first and second sub-pixels SPX1 and SPX2. For example, the surface area of the third sub-pixel SPX3 may be greater than the surface area of each of the first and second sub-pixel SPX1 and SPX2.

Referring to FIG. 2C, each of the first sub-pixel SPX1, the second sub-pixel SPX2, and the third sub-pixel SPX3 may have a hexagonal shape (or a regular hexagonal shape) in a plan view. In an embodiment, two adjacent sides of six sides of each of the first to third sub-pixels SPX1 to SPX3 may face corresponding sides of adjacent sub-pixels.

The first sub-pixel SPX1 may emit a first color of light. The second sub-pixel SPX2 may emit a second color of light. The third sub-pixel SPX3 may emit a third color of light. The first color of light may be light in a red wavelength band. The second color of light may be light in a green wavelength band. The third color of light may be light in a blue wavelength band. The red wavelength band may be a wavelength band ranging from approximately 600 nm to approximately 750 nm. The green wavelength band may be a wavelength band ranging from approximately 480 nm to approximately 560 nm. The blue wavelength band may be a wavelength band ranging from approximately 370 nm to approximately 460 nm. However, embodiments of the disclosure are not limited to the foregoing.

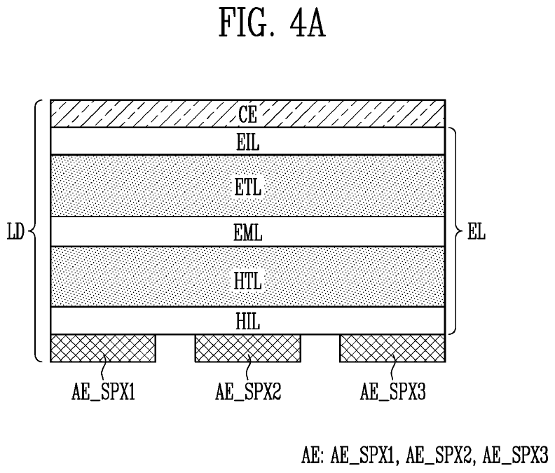

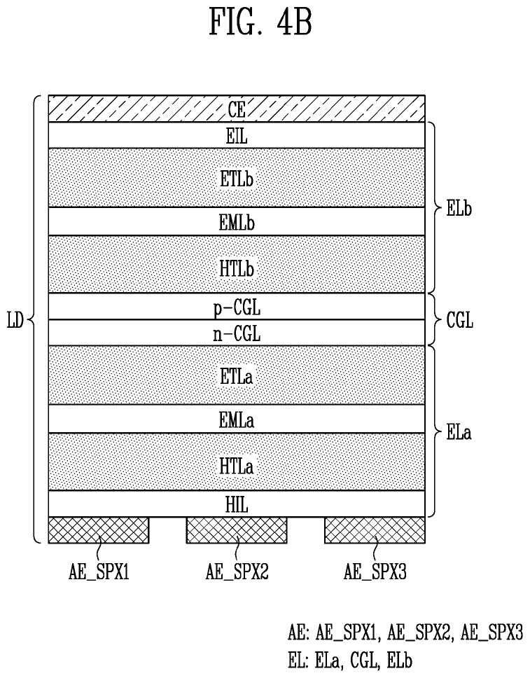

Each of the first sub-pixel SPX1, the second sub-pixel SPX2, and the third sub-pixel SPX3 may include a light emitting element (e.g., a light emitting element LD of FIGS. 4A and 4B) configured to emit light. The light emitting element may include an organic light emitting element having an organic layer.

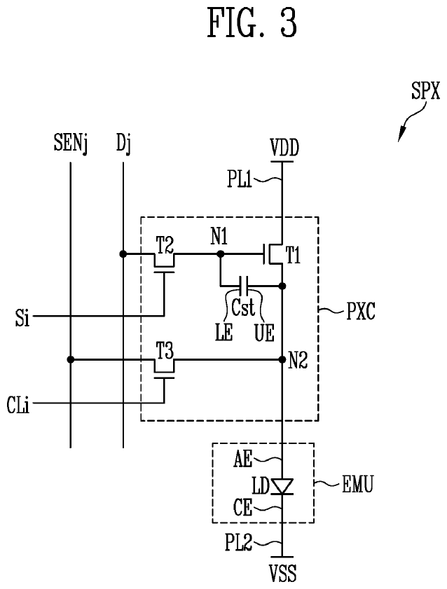

FIG. 3 is a schematic diagram of an equivalent circuit of a sub-pixel SPX included in the pixel PX of FIGS. 2A to 2C.

The sub-pixel SPX illustrated in FIG. 3 may be any one of the sub-pixels SPX1 to SPX3 illustrated in FIGS. 2A to 2C. The sub-pixels SPX1 to SPX3 arranged in a display area of the display device DD may have a substantially identical or similar configuration.

For the sake of explanation, FIG. 3 illustrates a sub-pixel SPX positioned on an i-th pixel row (or an i-th horizontal line) and a j-th pixel column (where each of i and j may be a natural number greater than 0).

Referring to FIG. 3, the sub-pixel SPX may include an emission component EMU configured to generate light having a luminance corresponding to a data signal. Furthermore, the sub-pixel SPX may further include a pixel circuit PXC configured to drive the emission component EMU.

The emission component EMU may include a light emitting element LD electrically connected between a first power line PL1 provided to receive a voltage from a first driving power supply VDD (or a first power supply) and a second power line PL2 provided to receive a voltage from a second driving power supply VSS (or a second power supply). For example, the emission component EMU may include a light emitting element LD which includes a first pixel electrode AE electrically connected to the first driving power supply VDD via the pixel circuit PXC and the first power line PL1, and a second pixel electrode CE electrically connected to the second driving power supply VSS via the second power line PL2. The first pixel electrode AE may be an anode, and the second pixel electrode CE may be a cathode. The first driving power supply VDD and the second driving power supply VSS may have different potentials. Here, a difference in potential between the first and second driving power supplies VDD and VSS may be set to a value equal to or greater than a threshold voltage of the light emitting elements LD during an emission period of the sub-pixel SPX.

In the case in which the sub-pixel SPX may be disposed on an i-th pixel row and a j-th pixel column in the display area of the display device DD, the pixel circuit PXC of the sub-pixel SPX may be electrically connected to an i-th scan line Si and a j-th data line Dj. Furthermore, the pixel circuit PXC may be electrically connected to an i-th control line CLi and a j-th sensing line SENj.

The pixel circuit PXC may include first to third transistors T1 to T3, and a storage capacitor Cst.

The first transistor T1 may be electrically connected between the first driving power supply VDD and the light emitting element LD as a driving transistor configured to control a driving current to be applied to the light emitting element LD. In detail, a first terminal of the first transistor T1 may be electrically connected to the first driving power supply VDD by the first power line PL1. A second terminal of the first transistor T1 may be electrically connected to a second node N2. A gate electrode of the first transistor T1 may be electrically connected to a first node N1. The first transistor T1 may control, in response to a voltage applied to the first node N1, the driving current to be applied from the first driving power supply VDD to the light emitting element LD through the second node N2. In an embodiment, the first terminal of the first transistor T1 may be a drain electrode, and the second terminal of the first transistor T1 may be a source electrode, and the disclosure may not be limited thereto. In an embodiment, the first terminal may instead be a source electrode, and the second terminal may instead be a drain electrode.

The second transistor T2 may be electrically connected between the j-th data line Dj and the first node N1 as a switching transistor to select a sub-pixel SPX in response to a scan signal and activate the sub-pixel SPX. A first terminal of the second transistor T2 may be electrically connected to the j-th data line Dj. A second terminal of the second transistor T2 may be electrically connected to the first node N1 (or the gate electrode of the first transistor T1). A gate electrode of the second transistor T2 may be electrically connected to the i-th scan line Si. The first terminal and the second terminal of the second transistor T2 may be different terminals, and, for example, if the first terminal is a drain electrode, the second terminal may be a source electrode.

In case that a scan signal having a gate-on voltage (e.g., a high level voltage) is supplied from the i-th scan line Si, the second transistor T2 may be turned on to electrically connect the j-th data line Dj to the first node N1. The first node N1 may be a point at which the second terminal of the second transistor T2 and the gate electrode of the first transistor T1 are electrically connected to each other. The second transistor T2 may transmit a data signal to the gate electrode of the first transistor T1.

The third transistor T3 may electrically connect the first transistor T1 to the j-th sensing line SENj, and thus a sensing signal may be obtained through the j-th sensing line SENj, and characteristics of the sub-pixel SPX such as a threshold voltage of the first transistor T1 may be detected using the sensing signal. Information about the characteristics of each sub-pixel SPX may be used to convert image data such that a deviation in characteristics between sub-pixels SPX can be compensated for. A second terminal of the third transistor T3 may be electrically connected to the second terminal of the first transistor T1. A first terminal of the third transistor T3 may be electrically connected to the j-th sensing line SENj. A gate electrode of the third transistor T3 may be electrically connected to the i-th control line CLi. The first terminal may be a drain electrode, and the second terminal may be a source electrode.

The third transistor T3 may be an initialization transistor configured to initialize the second node N2, and may be turned on in case that a sensing control signal may be supplied thereto from the i-th control line CLi, thus allowing the voltage of the initialization power supply to be transmitted to the second node N2. Hence, the storage capacitor Cst electrically connected to the second node N2 may be initialized.

The storage capacitor Cst may include a lower electrode LE (or a first storage electrode) and an upper electrode UE (or a second storage electrode). The lower electrode LE may be electrically connected to the first node N1. The upper electrode UE may be electrically connected to the second node N2. The storage capacitor Cst may be charged with a data voltage corresponding to a data signal to be supplied to the first node N1 during a frame period. Hence, the storage capacitor Cst may store a voltage corresponding to a difference between a voltage of the gate electrode of the first transistor T1 and a voltage of the second node N2.

Although FIG. 3 illustrates an embodiment where all of the first to third transistors T1 to T3 may be N-type transistors, the disclosure may not be limited thereto. For example, at least one of the first to third transistors T1 to T3 may instead be changed to a P-type transistor. The structure of the pixel circuit PXC may be changed in various ways.

FIG. 4A is a schematic sectional view illustrating an embodiment of the light emitting element LD of FIG. 3.

Referring to FIG. 4A, the light emitting element LD may include a first pixel electrode AE, an emission layer EL, and a second pixel electrode CE that may be successively stacked on each other.

In an embodiment, the first pixel electrode AE may be patterned to correspond to first to third sub-pixels (e.g., the first to third sub-pixels SPX1 to SPX3 of FIGS. 2A to 2C). In an embodiment, the first pixel electrode AE may include first pixel electrodes AE_SPX1 to AE_SPX3 that respectively correspond to the first to third sub-pixels SPX1 to SPX3. The first pixel electrode AE_SPX1 may be a pixel electrode corresponding to the first sub-pixel SPX1. The first pixel electrode AE_SPX2 may be a pixel electrode corresponding to the second sub-pixel SPX2. The first pixel electrode AE_SPX3 may be a pixel electrode corresponding to the third sub-pixel SPX3.

In an embodiment, the emission layer EL for each pixel and sub-pixel may be integral, and the second pixel electrode CE for each pixel and sub-pixel may be integral. The emission layer EL may be disposed on the first pixel electrode AE. In an embodiment, the emission layer EL may be integrally provided on the first pixel electrodes AE_SPX1 to AE_SPX3 that may be patterned to correspond to the first to third sub-pixels SPX1 to SPX3. The disclosure may not be limited thereto. In an embodiment, the second pixel electrode CE may be disposed on the emission layer EL.

The emission layer EL may include a hole injection layer HIL, a hole transport layer HTL, an organic emission layer EML, an electron transport layer ETL, and an electron injection layer EIL that may be successively stacked on each other.

The hole injection layer HIL may be an organic layer that may be disposed between the first pixel electrode AE and the hole transport layer HTL to facilitate injection of holes from the first pixel electrode AE to the organic emission layer EML. The hole transport layer HTL may be disposed between the hole injection layer HIL and the organic emission layer EML to receive holes from the first pixel electrode AE and transport the holes to the organic emission layer EML.

The electron injection layer EIL may be disposed between the electron transport layer ETL and the second pixel electrode CE. The electron transport layer ETL may be disposed on the organic emission layer EML and function to receive electrons from the second pixel electrode CE and transmit the electrons to the organic emission layer EML.

The organic emission layer EML may be an area where light may be generated by combination of holes and electrons that may be supplied from the first pixel electrode AE and the second pixel electrode CE respectively. The organic emission layer EML may include organic light-emitting material such as high-molecular organic material or low-molecular organic material, which may emit a certain color of light. For example, the organic emission layer EML may be formed of an organic material that may emit blue light. However, the disclosure may not be limited thereto. In an embodiment, the organic emission layer EML may be formed of organic material that may instead emit red or green light, or may be formed of inorganic material or of quantum dots.

The second pixel electrode CE may be disposed on the emission layer EL. The second pixel electrode CE may be integral among light emitting elements LD.

FIG. 4B is a schematic sectional view illustrating an embodiment of the light emitting element LD of FIG. 3.

Referring to FIG. 4B, the light emitting element LD may include a first pixel electrode AE, an emission layer EL, and a second pixel electrode CE that may be successively stacked on each other.

The emission layer EL may include a first emission component ELa, a second emission component ELb, and a charge generation layer CGL disposed between the first emission component ELa and the second emission component ELb. The first emission component ELa may have a structure in which a hole injection layer HIL, a first hole transport layer HTLa, a first emission layer EMLa, and a first electron transport layer ETLa may be successively stacked on each other. The second emission component ELb may include a structure in which a second hole transport layer HTLb, a second emission layer EMLb, a second electron transport layer ETLb, and an electron injection layer EIL may be successively stacked on each other.

The charge generation layer CGL may be disposed between the first emission component ELa and the second emission component ELb. The charge generation layer CGL may function to supply charges to the first emission component ELa and the second emission component ELb. The charge generation layer CGL may include an n-type charge generation layer n-CGL configured to supply charges to the first emission component ELa, and a p-type charge generation layer p-CGL configured to supply holes to the second emission component ELb. The n-type charge generation layer n-CGL may include metal material as a dopant

Although FIG. 4B illustrates that two emission components may be stacked on each other and provided in the light emitting element LD, the disclosure may not be limited thereto. For example, the light emitting element LD may instead include three or more emission components.

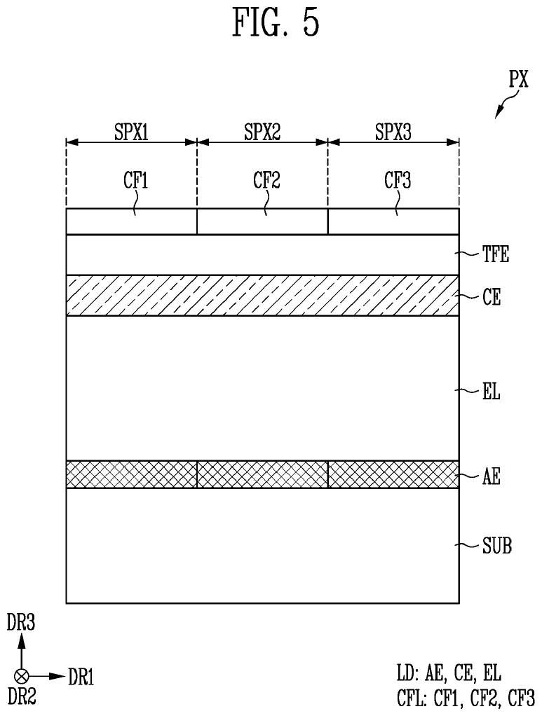

FIG. 5 is a schematic sectional view illustrating a stack structure of a pixel PX including the light emitting element LD of FIG. 3.

Referring to FIG. 5, the pixel PX may include a first substrate SUB, a light emitting element LD, an encapsulation layer TFE, and a color filter layer CFL.

The first substrate SUB may include a silicon substrate. The light emitting element LD may be disposed on the first substrate SUB. A pixel circuit layer (not illustrated) may be disposed between the first substrate SUB and the light emitting element LD. The pixel circuit layer may include various driving elements, lines, and the like for driving the light emitting element LD. For example, the pixel circuit layer may be formed of transistors (e.g., first to third transistors T1 to T3 in FIG. 3), a storage capacitor (e.g., the storage capacitor Cst in FIG. 3), a scan line, a data line, and the like, but the disclosure may not be limited thereto.

The light emitting element LD (or an organic light-emitting-element layer) may be disposed on the first substrate SUB. The light emitting element LD may include a first pixel electrode AE (or a first pixel electrode layer), an emission layer EL, and a second pixel electrode CE.

The first pixel electrode AE may be patterned separately for each of the first to third sub-pixels SPX1 to SPX3. The first pixel electrode AE, which supplies holes to the emission layer EL, may be made of transparent conductive material having a high work function.

The first pixel electrode AE may be formed of transparent conductive material such as tin oxide (TO), zinc oxide (ZnO), indium tin oxide (ITO), indium zinc oxide (IZO), indium tin zinc oxide (ITZO), or a combination thereof, but the disclosure may not be limited thereto.

The emission layer EL may be disposed between the first pixel electrode AE and the second pixel electrode CE. The emission layer EL may be an area where light may be emitted by combination of holes and electrons that may be supplied from the first pixel electrode AE and the second pixel electrode CE respectively.

The emission layer EL may be a white emission layer formed to emit white light. White light emitted from the emission layer EL may be converted to any one of red, green, and blue by the color filter layer CFL. The design of the emission layer EL may vary depending on a desired color of light to be emitted. For example, in the case where the emission layer EL includes a green emission layer, the emission layer EL may emit green light. In the case where the emission layer EL includes a red emission layer, the emission layer EL may emit red light.

The second pixel electrode CE may be disposed on the emission layer EL. The second pixel electrode CE may be formed of a single layer over an overall surface of the first substrate SUB. The respective second pixel electrodes CE of the first to third sub-pixels SPX1 to SPX3 may be electrically connected to each other to form an integrated structure. The second pixel electrode CE, which supplies electrons to the emission layer EL may be made of conductive material having a low work function. For example, the second pixel electrode CE may be formed of an ytterbium (Yb) alloy, or a transparent conductive material such as tin oxide (TO), zinc oxide (ZnO), indium tin oxide (ITO), indium zinc oxide (IZO), indium tin zinc oxide (ITZO), or a combination thereof. Furthermore, the second pixel electrode CE may be made of metal material such as silver (Ag), copper (Cu), a magnesium-silver (Mg—Ag) alloy, or a combination thereof and may be formed as an ultra thin metal layer, but the disclosure may not be limited thereto.

The encapsulation layer TFE may be disposed on the second pixel electrode CE. The encapsulation layer TFE may block penetration of water or oxygen from external environment, thus protecting the light emitting element LD. The encapsulation layer TFE may be a multilayer structure formed by alternately placing inorganic layers and organic layers.

The color filter layer CFL may be disposed on the encapsulation layer TFE. The color filter layer CFL may include first to third color filters CF1 to CF3 respectively corresponding to the first to third sub-pixels SPX1 to SPX3. The color filter layer CFL may convert white light emitted from the emission layer EL of the light emitting element LD to a certain color of light.

The first color filter CF1 may be disposed in an area corresponding to the first pixel electrode AE of the first sub-pixel SPX1. The first color filter CF1 allows a first color of light to selectively pass therethrough. For example, the first color filter CF1 may include a color filter material of the first color, allowing transmission of light of the first color while blocking light of the second and third colors.

The second color filter CF2 may be disposed in an area corresponding to the first pixel electrode AE of the second sub-pixel SPX2. For example, the second color filter CF2 may include a color filter material of the second color, allowing transmission of light of the second color while blocking light of the first and third colors.

The third color filter CF3 may be disposed in an area corresponding to the first pixel electrode AE of the third sub-pixel SPX3. For example, the third color filter CF3 may include a color filter material of the third color, allowing transmission of light of the third color while blocking light of the first and second colors.

In an embodiment, in the case where the first sub-pixel SPX1 is a red sub-pixel, the first color filter CF1 may include a red color filter. In the case where the second sub-pixel SPX2 is a green sub-pixel, the second color filter CF2 may include a green color filter. In the case where the third sub-pixel SPX3 is a blue sub-pixel, the third color filter CF3 may include a blue color filter.

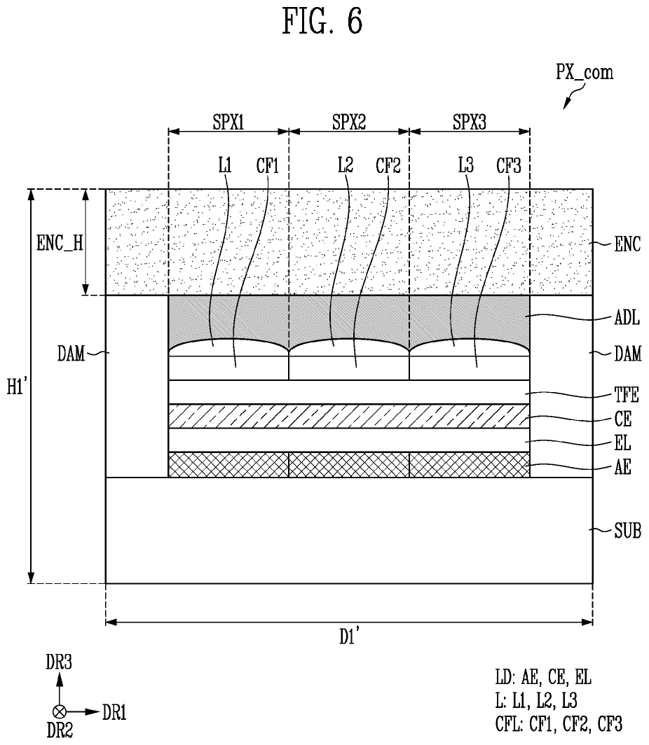

FIG. 6 is a schematic sectional view illustrating a comparative example of a pixel PX_com included in the display device DD.

Referring to FIG. 6, a pixel PX_com, which may be a comparative example, may include a first substrate SUB, a light emitting element LD, an encapsulation layer TFE, a color filter layer CFL, a lens layer L, an adhesive layer ADL, a dam structure DAM, and a second substrate ENC.

The lens layer L may be disposed on the color filter layer CFL. The lens layer L may include multiple lenses. Lenses L1 to L3 may be provided to respectively correspond to the first to third sub-pixels SPX1 to SPX3. The lens layer L functions to increase the extraction efficiency of light emitted from the light emitting element LD.

The damp structure DAM may be disposed on the first substrate SUB to enclose the light emitting element LD, the encapsulation layer TFE, the color filter layer CFL, the lens layer L, and the adhesive layer ADL. The dam structure DAM may be a structure for preventing the adhesive layer ADL formed on the lens layer L from overflowing to an adjacent pixel. The adhesive layer ADL may include material for planarizing a stepped portion formed on the lens layer L. For example, the adhesive layer ADL may include optically clear material.

The second substrate ENC may be disposed as a single layer over the overall surfaces of the dam structure DAM and the adhesive layer ADL. The second substrate ENC may cover the underlying components including the color filter layer CFL and the lens layer L.

According to the pixel PX_com illustrated in FIG. 6, the adhesive layer ADL may be disposed on the lens layer L, and the dam structure DAM may be disposed to receive the adhesive layer ADL.

In the pixel PX_com, the second substrate ENC having a height ENC_H may be disposed on the dam structure DAM. Hence, a height H1′ of the pixel PX_com may be formed to include the height ENC_H of the second substrate ENC. Furthermore, a width D1′ of the pixel PX_com may be formed to include a width of the dam structure DAM.

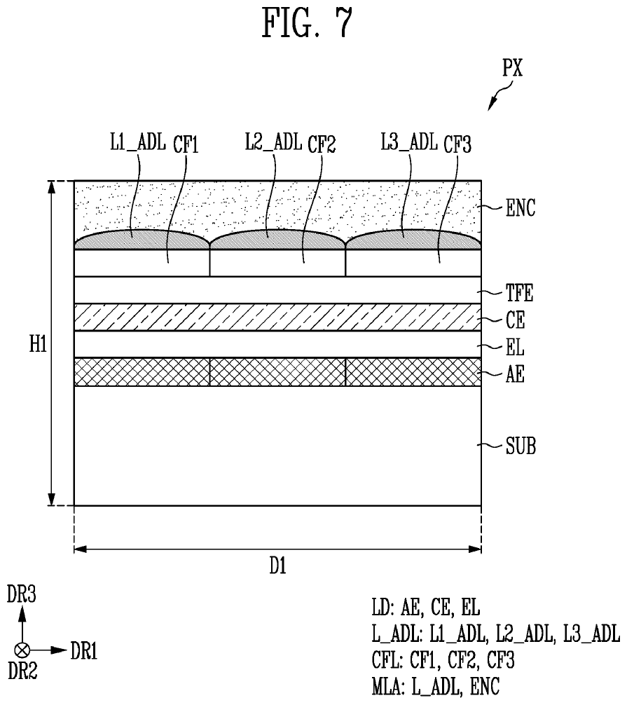

FIG. 7 is a schematic sectional view illustrating an embodiment of a stack structure and a lens array layer MLA of the pixel PX of FIG. 5.

Referring to FIG. 7, the pixel PX may include a first substrate SUB, a light emitting element LD, an encapsulation layer TFE, a color filter layer CFL, and a lens array layer MLA.

Except for the lens array layer MLA, the remaining components may be the same as the components illustrated in FIG. 5 and therefore a redundant explanation of the corresponding components will be omitted.

In an embodiment, the lens array layer MLA may be disposed on the color filter layer CFL. The lens array layer MLA may include a lens layer L_ADL and a second substrate ENC.

In an embodiment, the lens layer L_ADL may include multiple lenses L1_ADL to L3_ADL. The lenses L1_ADL to L3_ADL may be disposed on the color filter layer CFL. The lenses L1_ADL to L3_ADL may include a first lens L1_ADL, a second lens L2_ADL, and a third lens L3_ADL. In an embodiment, the first lens L1_ADL may be disposed on the first color filter CF1. The second lens L2_ADL may be disposed on the second color filter CF2. The third lens L3_ADL may be disposed on the third color filter CF3.

In an embodiment, the diameter of each of the lenses L1_ADL to L3_ADL may be approximately 10 μm or less. However, the disclosure may not be limited thereto. For example, the diameter may instead be greater than 10 μm.

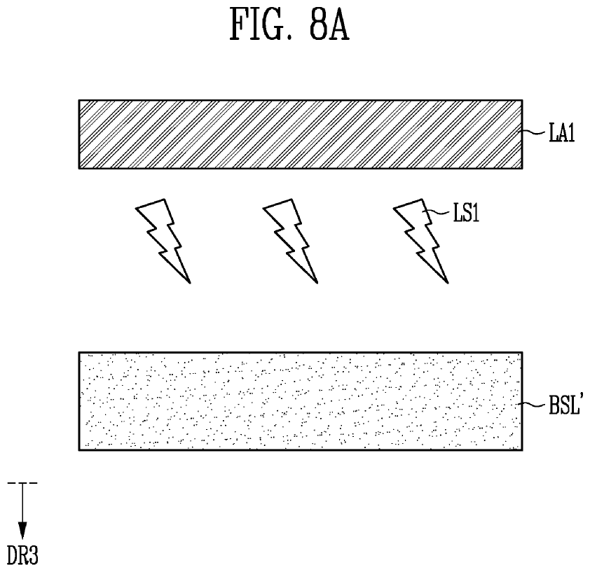

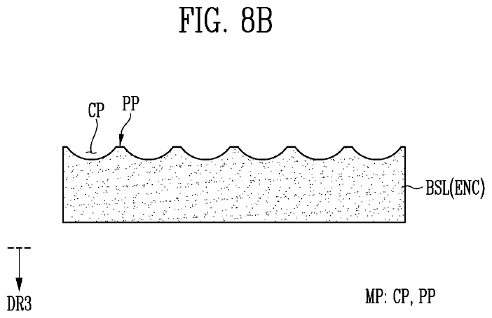

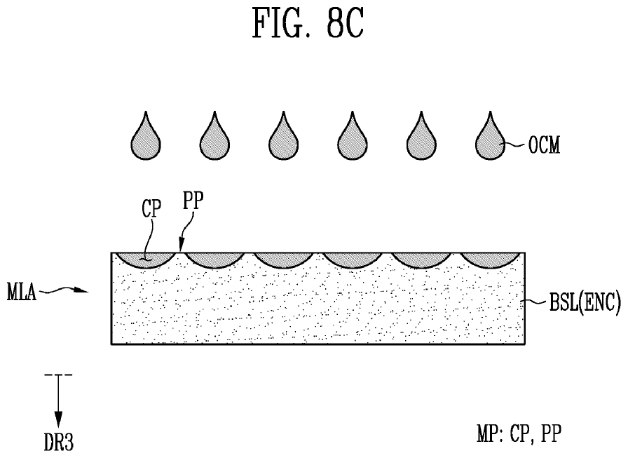

In an embodiment, the lenses L1_ADL to L3_ADL may include optically clear material OCM (refer to FIG. 8C). The optically clear material OCM may include at least one of optically clear resin (OCR) and optically clear adhesive (OCA). The lens layer L_ADL may be designed to concentrate light that may be emitted from the emission layer EL and passes through the color filter layer CFL. In other words, the lens layer L_ADL may function to increase the extraction efficiency of light emitted from the light emitting element LD.

In an embodiment, the second substrate ENC may be disposed (e.g., directly disposed) on the lens layer L_ADL. The second substrate ENC may include multiple concave depressions or concave recesses (e.g., concave depressions CP in FIGS. 8B and 8C) formed to receive the lens layer L_ADL. The concave depressions may correspond to the shapes of the lenses L1_ADL to L3_ADL. For example, the second substrate ENC may include a concave depression (or a first concave depression) corresponding to the first lens L1_ADL, a concave depression (or a second concave depression) corresponding to the second lens L2_ADL, and a concave (or a third concave depression) corresponding to the third lens L3_ADL.

In an embodiment, the shapes of the lenses L1_ADL to L3_ADL may be determined by the concave depressions. For example, in the case where the concave depressions have a same shape, the shapes of the lenses L1_ADL to L3_ADL may be the same as each other.

In an embodiment, the second substrate ENC may include a glass substrate.

In an embodiment, the second substrate ENC may receive (and protect) the lens layer L_ADL and also cover the underlying components including the color filter layer CFL disposed under the lens layer L_ADL. The second substrate ENC may prevent water or air from penetrating into the lens layer L_ADL and the underlying components including the color filter layer CFL. Furthermore, the second substrate ENC may protect the lens layer L_ADL and the color filter layer CFL from foreign substances such as dust particles.

In accordance with an embodiment of the disclosure, the pixel PX (or the display device DD) may be configured such that the second substrate ENC may be disposed (e.g., directly disposed) on the lens layer L_ADL, thus removing the need for a separate adhesive layer (e.g., the adhesive layer ADL in FIG. 6). As a result, the height of the pixel PX in the third direction DR3 may be reduced. In other words, a height H1 of the pixel PX may be less than the height H1′ of the pixel PX_com corresponding to the comparative example of FIG. 6.

Furthermore, in accordance with an embodiment of the present disclosure, the pixel PX (or the display device DD) does not require a separate adhesive layer (e.g., the adhesive layer ADL shown in FIG. 6), and therefore a dam structure (e.g., the dam structure DAM shown in FIG. 6) that may be used to receive the adhesive layer may not be needed. As a result, the width of the pixel PX in the first direction DR1 may be reduced. In other words, a width D1 of the pixel PX may be less than the width D1′ of the pixel PX_com corresponding to the comparative example of FIG. 6.

Consequently, the pixel PX (or the display device DD) in accordance with an embodiment of the disclosure may contribute to the miniaturization of the pixel PX (or the display device DD).

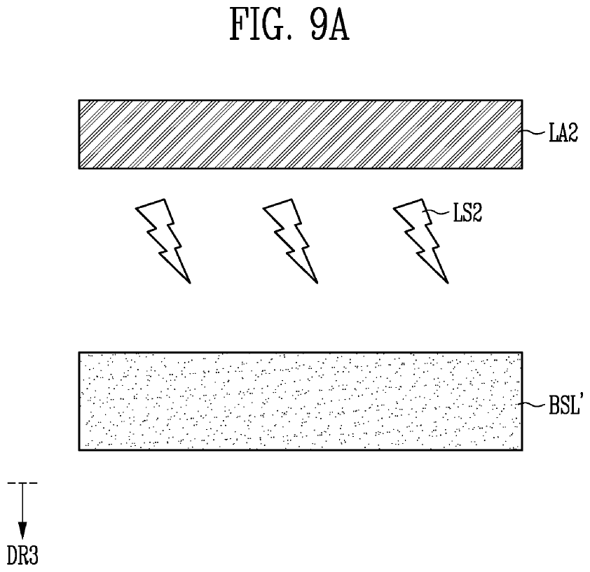

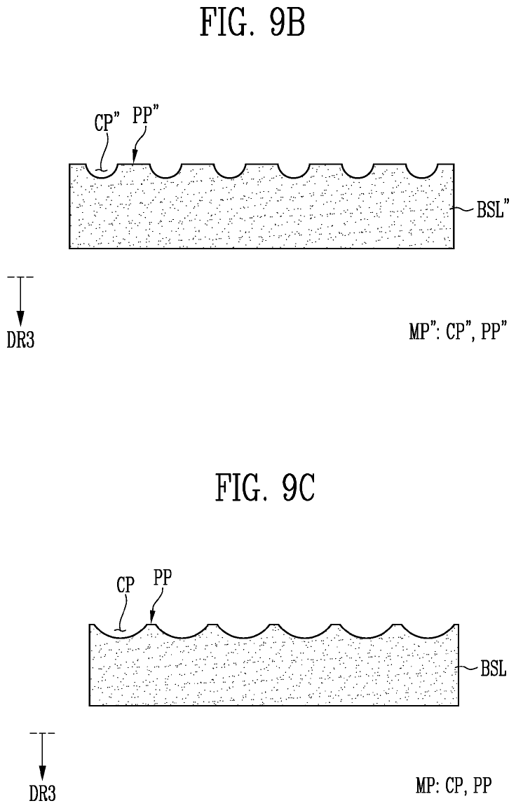

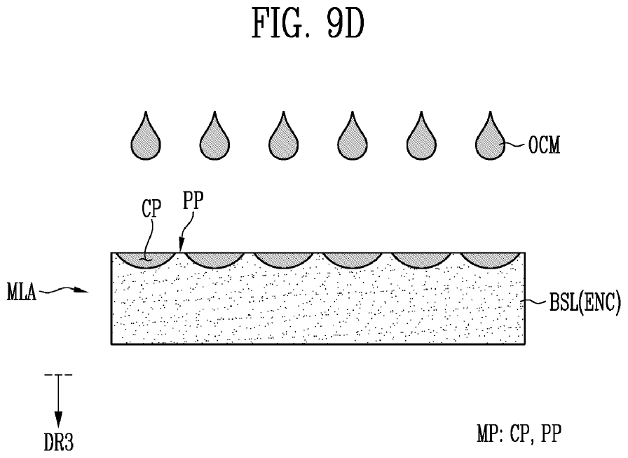

A method of fabricating the lens array layer MLA will be described below with reference to FIGS. 8A to 8C and 9A to 9D.

FIGS. 8A to 8C are schematic diagrams successively illustrating an embodiment of a method of fabricating the lens array layer MLA of FIG. 7.

Referring to FIGS. 8A to 8C, the method of fabricating the lens array layer MLA may include the step of forming a micro-pattern MP including concave depressions (or concave recesses) CP in a base substrate BSL′ (refer to FIGS. 8A to 8B), and the step of ejecting optically clear material OCM into the concave depressions CP (refer to FIG. 8C).

Referring to FIGS. 8A and 8B, multiple concave depressions CP may be formed in a surface of the base substrate BSL′ through a laser direct patterning process. The laser direct patterning process may include a process of irradiating a first laser beam LS1 onto the base substrate BSL′ from a first laser device LA1. The first laser beam LS1 may be within an ultraviolet wavelength range. For example, the first laser beam LS1 may have a wavelength ranging from approximately 100 nm to approximately 400 nm.

The micro-pattern MP may be formed in the base substrate BSL (or the second substrate ENC) through the laser direct patterning process. The micro-pattern MP may include multiple concave depressions CP and protrusions PP. The irradiation of the first laser beam LS1 onto certain areas of the base substrate BSL′ may result in removal of the certain areas, thus forming the concave depressions CP. The concave depressions CP may be spaced apart from each other and arranged in one direction (e.g., the first direction DR1 of FIG. 7).

Referring to FIG. 8C, the concave depressions CP of the base substrate BSL (or the second substrate ENC) may be filled with the optically clear material OCM. In an embodiment, the optically clear material OCM may be ejected onto the base substrate BSL in the third direction DR3 so that the concave depressions CP can be filled with the optically clear material OCM. In an embodiment, as the concave depressions CP are filled with the optically clear material OCM, the optically clear material OCM may form a lens layer (e.g., the lens layer L_ADL in FIG. 7). In an embodiment, the base substrate BSL (or the second substrate ENC) and the optically clear material OCM deposited into the concave depressions CP may be integrated with each other, thus forming the lens array layer MLA.

FIGS. 9A to 9D are schematic diagrams successively illustrating an embodiment of the method of fabricating the lens array layer MLA of FIG. 7.

Referring to FIGS. 9A to 9D, the method of fabricating the lens array layer MLA may include the step of forming a micro-pattern MP including concave depressions CP in a base substrate BSL′ (refer to FIGS. 9A to 9C), and the step of ejecting optically clear material OCM into the concave depressions CP (refer to FIG. 9D).

Referring to FIGS. 9A to 9C, multiple concave depressions CP may be formed in a surface of the base substrate BSL′ through a laser patterning process and a chemical etching process.

Referring to FIGS. 9A and 9B, a second laser beam LS2 may be irradiated onto the base substrate BSL′ from a second laser device LA2. The second laser beam LS2 may be within an infrared wavelength range. For example, the second laser beam LS2 may have a wavelength ranging from approximately 750 nm to approximately 1000 nm. As the second laser beam LS2 may be irradiated onto the base substrate BSL′, the bonding characteristics of the material constituting the base substrate BSL′ may be changed. Hence, the surface characteristics of the area of the base substrate BSL′ onto which the second laser beam LS2 may be irradiated may be changed.

Referring to FIG. 9B, a micro-pattern MP″ may be formed in the base substrate BSL″ through the laser patterning process. The micro-pattern MP″ may include multiple concave depressions CP″ and protrusions PP″. The concave depressions CP″ may be formed by irradiating the second laser beam LS2 onto certain areas of the base substrate BSL′. The concave depressions CP″ may be spaced apart from each other and arranged in one direction (e.g., the first direction DR1 of FIG. 7). The concave depressions CP″ may be areas where the surface of the base substrate BSL′ has been deformed by irradiating the second laser beam LS2 thereon.

Referring to FIG. 9C, micro-patterns MP may be formed in the base substrate BSL through a chemical etching process performed on the base substrate BSL″. The micro-pattern MP may include multiple concave depressions CP and protrusions PP.

The chemical etching process may be performed on the base substrate BSL″ by spraying a chemical solution onto the base substrate BSL″. As the chemical solution penetrates into the concave depressions CP″, multiple concave depressions CP having depths greater than that of the concave depressions CP″ of FIG. 9B may be formed. The chemical solution may include at least one of hydrogen fluoride (HF) solution, potassium hydroxide (KOH) solution, and sodium hydroxide (NaOH) solution.

Referring to FIG. 9D, the concave depressions CP of the base substrate BSL (or the second substrate ENC) may be filled with optically clear material OCM. In an embodiment, the optically clear material OCM may be ejected onto the base substrate BSL so that the concave depressions CP can be filled with the optically clear material OCM. In an embodiment, as the concave depressions CP may be filled with the optically clear material OCM, the optically clear material OCM may form a lens layer (e.g., the lens layer L_ADL in FIG. 7). In an embodiment, the base substrate BSL (or the second substrate ENC) and the optically clear material OCM deposited into the concave depressions CP may be integrated with each other, thus forming the lens array layer MLA.

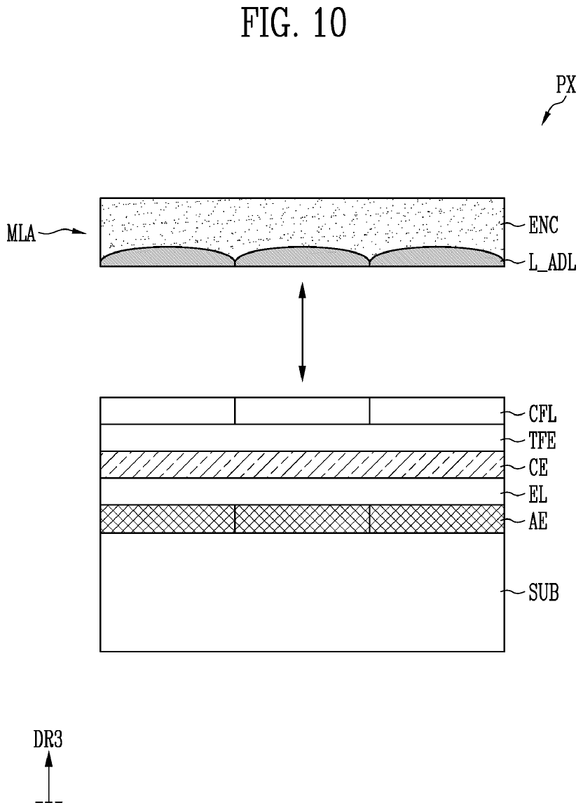

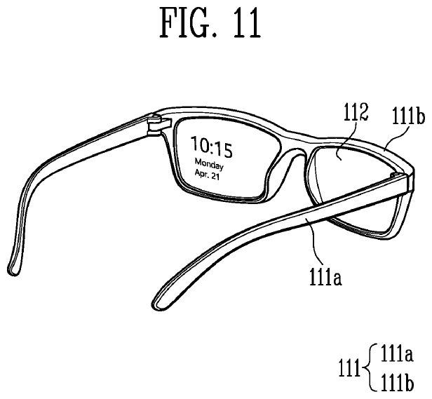

FIG. 10 is a schematic sectional view illustrating a method of fabricating the display device DD of FIG. 1.

Referring to FIG. 10, the lens array layer MLA fabricated with reference to FIGS. 8A to 8C or FIG. 9A to 9D may be bonded to a stack structure of the pixel PX. The display device (e.g., the display device DD in FIG. 1) may be formed by bonding the lens array layer MLA to the stack structure of the pixel PX.

Referring to FIGS. 8C, 9D, and 10, the lens array layer MLA illustrated in FIGS. 8C and 9D may be inverted in the third direction DR3 so that the lens layer L_ADL of the lens array layer MLA can be positioned facing the color filter layer CFL. In an embodiment, multiple lenses that constitute the lens layer L_ADL may be respectively disposed to face the color filters that constitute the color filter layer CFL.

The method of fabricating the display device in accordance with the disclosure may include filling the concave depressions CP formed in the second substrate ENC with the optically transparent material ADL, thus forming an integral lens array layer MLA that includes the lens layer L_ADL. As a result, there is no need for a process of applying an adhesive layer to couple the second substrate ENC on the lens layer L_ADL. Consequently, the process of fabricating the display device may be simplified and streamlined, so that the process efficiency can be improved.

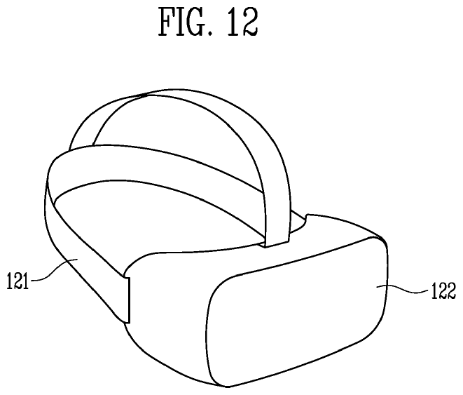

FIGS. 11 and 12 illustrate examples of an electronic device including the display device DD of FIG. 1.

Referring to FIG. 11, the display device in accordance with the aforementioned embodiments may be applied to smart glasses. The smart glasses may include a frame 111 and a lens component 112. The smart glasses may be a wearable electronic device, which may be worn on the face of the user, and may have a structure such that a portion of the frame 111 can be folded or unfolded. For example, the smart glasses may be a wearable device for augmented reality (AR).

The frame 111 may include a housing 111b which support the lens component 112, and a leg component 111a enabling the user to wear the smart glasses. The leg component 111a may extend from the housing 111b by a hinge and thus can be folded or unfolded.

The frame 111 may be equipped with a battery, a touch pad, a microphone, and/or a camera. Furthermore, the frame 111 may be equipped with a projector configured to output light, and/or a processor configured to control a light signal.

The lens component 112 may be an optical component configured to transmit or reflect light. The lens component 112 may include glass, and/or transparent synthetic resin.

The display device in accordance with the aforementioned embodiments may be applied to the lens component 112. For example, the user may perceive images displayed by optical signals transmitted from the projector in the frame 111 by way of the lens component 112. For example, the user may perceive information such as time and date data displayed on the lens component 112.

Referring to FIG. 12, the display device in accordance with the aforementioned embodiments may be applied to a head mounted display (HMD). The HMD may include a head mounting band 121 and a display receiving case 122. For example, the HMD may be a wearable electronic device, which can be worn on the head of the user.

The head mounting band 121 may extend from the display receiving case 122 and serve to mount the display receiving case 122 on the head of the user. As illustrated in FIG. 12, the head mounting band 121 may include a horizontal band and a vertical band for mounting the HMD to the head of the user, and may be configured such that the horizontal band may enclose a side portion of the head of the user while the vertical band may enclose an upper portion of the head of the user. However, the disclosure may not be limited to the foregoing embodiments. For example, the head mounting band 121 may instead be implemented in the form of an eyeglass frame or a helmet.

The display receiving case 122 may receive the display device, and include at least one lens. The at least one lens may provide an image to the user. For example, the display device in accordance with the aforementioned embodiments may be applied to a left-eye lens and a right-eye lens that may be implemented in the display receiving case 122.

A display device in accordance with embodiments of the disclosure may be designed such that a substrate including multiple concave depressions that receive multiple lenses may be disposed on the color filter layer, whereby the thickness of the display device and the width of each pixel included in the display device can be reduced. Consequently, the resolution of the display device may be improved.

Furthermore, in a method of fabricating the display device in accordance with an embodiment, there may be no need for a process of applying an adhesive layer for disposing a substrate on multiple lenses. As a result, the process of fabricating the display device may be streamlined and simplified, so that the process efficiency can be enhanced.

However, effects of the disclosure may not be limited to the above-described effects, and various modifications may be possible without departing from the spirit and scope of the disclosure.

While embodiments of the disclosure have been described above, those skilled in the art will appreciate that various modifications, additions and substitutions may be possible, without departing from the scope and spirit of the disclosure claimed in the claims.

What is claimed is:

1. A display device, comprising:
a first substrate;
an organic light-emitting-element layer disposed on the first substrate;
an encapsulation layer disposed on the organic light-emitting-element layer; and
a lens array layer disposed on the encapsulation layer, wherein
the lens array layer comprises:
a lens layer including a plurality of lenses; and
a second substrate disposed directly on the plurality of lenses, and
the second substrate includes a plurality of concave depressions corresponding to shapes of the plurality of lenses.

2. The display device according to claim 1, wherein the plurality of lenses include an optically clear material.

3. The display device according to claim 2, wherein the plurality of lenses include at least one of an optically clear resin (OCR) and an optically clear adhesive (OCA).

4. The display device according to claim 2, further comprising:
a color filter layer disposed between the encapsulation layer and the lens array layer, the color filter layer including first to third color filters,
wherein the plurality of lenses comprise:
a first lens disposed on the first color filter;
a second lens disposed on the second color filter; and
a third lens disposed on the third color filter.

5. The display device according to claim 4, wherein
the plurality of concave depressions include a first concave depression, a second concave depression, and a third concave depression,
the first lens is disposed in the first concave depression,
the second lens is disposed in the second concave depression, and
the third lens is disposed in the third concave depression.

6. The display device according to claim 1, wherein the second substrate comprises a glass substrate.

7. The display device according to claim 4, wherein
the first substrate includes first to third sub-pixels, and
the organic light-emitting-element layer comprises:
a first pixel electrode layer including respective first pixel electrodes of the first to third sub-pixels, the first pixel electrodes being spaced apart from each other;
an emission layer disposed on the first pixel electrode layer; and
a second pixel electrode disposed on the emission layer.

8. The display device according to claim 7, wherein
the first pixel electrode of the first sub-pixel overlaps the first color filter,
the first pixel electrode of the second sub-pixel overlaps the second color filter, and
the first pixel electrode of the third sub-pixel overlaps the third color filter.

9. The display device according to claim 1, wherein the first substrate comprises a silicon substrate.

10. The display device according to claim 1, wherein the plurality of lenses have a same shape.

11. A method of fabricating a display device, comprising:
providing a pixel having a stack structure, the pixel including an organic light-emitting-element layer;
providing a base substrate;
forming a micro-pattern including a plurality of concave depressions in the base substrate;
filling the plurality of concave depressions with an optically clear material; and
disposing the base substrate over the pixel.

12. The method according to claim 11, wherein the forming of the micro-pattern comprises removing portions of the base substrate by irradiating a laser beam onto the base substrate.

13. The method according to claim 12, wherein the laser beam has a wavelength in a range of approximately 100 nm to approximately 400 nm.

14. The method according to claim 12, wherein
the forming of the micro-pattern further comprises etching the base substrate using a chemical solution, and
the laser beam has a wavelength in a range of approximately 750 nm to approximately 1000 nm.

15. The method according to claim 11, further comprising:
forming a color filter layer on the organic light-emitting-element layer,
wherein the plurality of concave depressions filled with the optically clear material directly contact an upper surface of the color filter layer.

16. The method according to claim 11, wherein in the forming of the micro-pattern, the plurality of concave depressions are spaced apart from each other.

17. The method according to claim 11, wherein the base substrate comprises a glass substrate.

18. The method according to claim 11, wherein the optically clear material includes at least one of an optically clear resin (OCR) and an optically clear adhesive (OCA).

19. The method according to claim 15, wherein the stack structure comprises:
a first substrate;
the organic light-emitting-element layer disposed on the first substrate;
an encapsulation layer disposed on the organic light-emitting-element layer; and
the color filter layer disposed on the encapsulation layer, the color filter layer including first to third color filters, the first to third color filters being spaced apart from each other in a first direction.

20. The method according to claim 19, wherein
the plurality of concave depressions include a first concave depression, a second concave depression, and a third concave depression,
the first concave depression overlaps the first color filter,
the second concave depression overlaps the second color filter, and
the third concave depression overlaps the third color filter.
